(19) United States
(12) Patent Application Publication
(10) Pub. No.: US 2015/0029792 A1
(43) Pub. Date: Jan. 29, 2015

(54) SEMICONDUCTOR MEMORY DEVICE AND METHOD OF OPERATING THE SAME

(71) Applicant: SK hynix Inc., Icheon-si (KR)

(72) Inventor: Yoo Nam JEON, Seongnam-si (KR)

(73) Assignee: SK hynix Inc., Icheon-si (KR)

(21) Appl. No.: 14/078,090

(22) Filed: Nov. 12, 2013

(30) Foreign Application Priority Data
Jul. 26, 2013 (KR) 10-2013-0088748

(51) Int. Cl. G11C 16/04; G11C 16/10

(52) U.S. Cl. CPC G11C 16/0483; G11C 16/10
USPC 365/185.17

(57) ABSTRACT

A semiconductor memory device and a method of operating the same are provided. When threshold voltages of memory cells are boosted to use the memory cells as a selection transistor, a threshold voltage of an outermost memory cell may be boosted to the highest level so that a leakage current can be reduced and a channel boosting level can be increased to reduce the influence of program disturbance.

### CROSS-REFERENCE TO RELATED APPLICATION

The present application claims priority to Korean patent application number 10-2013-0088748 filed on Jul. 26, 2013, in the Korean Intellectual Property Office, the entire disclosure of which is incorporated by reference herein.

### BACKGROUND

1. Technical Field

The present invention relates to an electronic device, and more particularly, to a semiconductor memory device and a method of operating the same.

2. Related Art

Semiconductor memory devices are broadly classified into volatile semiconductor memory devices and nonvolatile semiconductor memory devices.

Although a volatile semiconductor memory device reads and writes data at a high speed, the volatile semiconductor memory device loses stored data if external power supply is interrupted. A nonvolatile semiconductor memory device reads and writes data at a relatively low speed, but the nonvolatile semiconductor memory device retains stored data even if external power supply is interrupted. Accordingly, the nonvolatile semiconductor memory device is used to store data to that needs to be retained even if power to the device is interrupted. The nonvolatile semiconductor memory devices may be divided into read-only memory (ROM) devices, mask ROM (MROM) devices, programmable ROM (PROM) devices, erasable programmable ROM (EPROM) devices, electrically erasable programmable ROM (EEPROM) devices, flash memory devices, phase-change random access memory (PRAM) devices, magnetic RAM (MRAM) devices, resistive RAM (RRAM) devices, and ferroelectric RAM (FRAM) devices. The flash memory devices may be divided into a NOR type and a NAND type.

A flash memory device may have the same advantage as RAM in that data may be freely programmed into a flash memory device and erased from the flash memory device. A flash memory device may have the same advantage as a ROM in that stored data may be retained even if power supply is interrupted. Thus, flash memory has widely been used as a storage medium of a portable electronic device, such as a digital camera, a personal digital assistant (PDA), and an MP3 player.

The reliability of a semiconductor memory device may be degraded due to various causes.

The semiconductor memory device may be configured to have high data reliability.

### SUMMARY

The present invention is directed to a semiconductor memory device having high data reliability and a method of operating the same.

One aspect of the present invention provides a cell string including first memory cells configured to store data, and second memory cells configured to be programmed and operate as a connection circuit between the first memory cells and an internal line. Control gates of the second memory cells may be integrally connected.

Another aspect of the present invention provides a semiconductor memory device including a cell string including first memory cells configured to store data and second memory cells configured to be programmed and operate as a connection circuit between the first memory cells and an internal line, control gates of the second memory cells being integrally connected, and a peripheral circuit configured to program the second memory cells such that one of the second memory cells, which is disposed at a farthest distance from the first memory cells, has a highest threshold voltage.

Another aspect of the present invention provides a method of operating a semiconductor memory device. The method includes providing a cell string including first memory cells configured to store data and second memory cells configured to be programmed and operate as a connection circuit between the first memory cells and an internal line, control gates of the second memory cells being integrally connected, programming the second memory cells such that one of the second memory cells, which is disposed at a farthest distance from the first memory cells, has a highest threshold voltage, and programming a selected memory cell of the first memory cells.

### BRIEF DESCRIPTION OF THE DRAWINGS

The above and other features and advantages of the disclosed embodiments will become more apparent to those of ordinary skill in the art by describing in detail example embodiments thereof with reference to the attached drawings in which:

FIG. 1 is a block diagram of a semiconductor memory device according to an example embodiment of the present disclosure;

FIG. 2 is a circuit diagram of a memory block shown in FIG. 1;

FIGS. 3A through 3C are diagrams for describing a relationship between threshold voltages of drain selection cells shown in FIG. 2 and channel boosting;

FIG. 4 is a conceptual diagram illustrating a method of operating a semiconductor memory device according to an example embodiment of the present disclosure;

FIG. 5 is a conceptual diagram illustrating a method of operating a semiconductor memory device according to another example embodiment of the present disclosure;

FIG. 6 is a conceptual diagram illustrating a method of operating a semiconductor memory device according to another example embodiment of the present disclosure;

FIG. 7 is a conceptual diagram illustrating a method of operating a semiconductor memory device according to another example embodiment of the present disclosure;

FIG. 8 is a flowchart illustrating a method of operating a semiconductor memory device according to another example embodiment of the present disclosure;

FIG. 9 is a detailed flowchart of step 210 shown in FIG. 8;

FIG. 10 is a detailed flowchart of step 220 shown in FIG. 8;

FIG. 11 is a detailed flowchart illustrating a method of operating the semiconductor memory device shown in FIG. 8;

FIG. 12 is a simplified block diagram of a memory system according to an example embodiment of the present disclosure;

FIG. 13 is a simplified block diagram of a fusion memory device or fusion memory system configured to perform a program operation according to the above-described various embodiments of the present disclosure; and

FIG. 14 is a simplified block diagram of a computing system including a flash memory device according to an example embodiment of the present invention.

### DETAILED DESCRIPTION

The present invention will now be described more fully hereinafter with reference to the accompanying drawings, in which example embodiments of the present invention are shown. This invention may, however, be embodied in different forms and should not be construed as limited to the embodiments set forth herein. Rather, these embodiments are provided so that this disclosure is thorough and fully conveys a scope of the present invention to one skilled in the art.

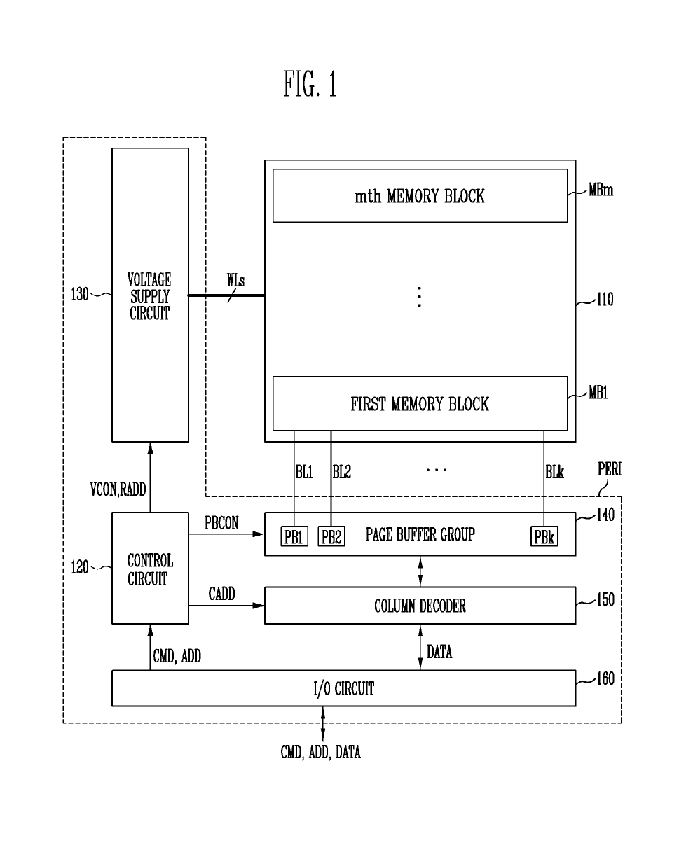

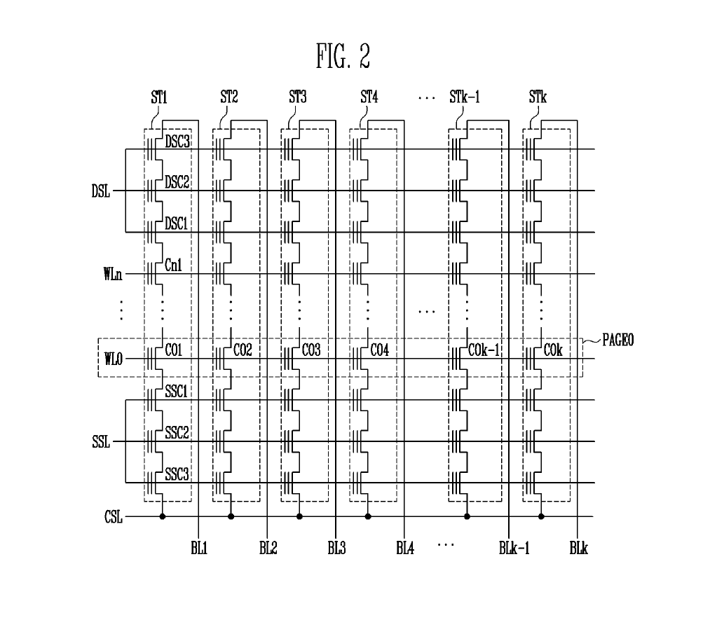

FIG. 1 is a circuit diagram of a semiconductor memory device according to an example embodiment of the present disclosure. FIG. 2 is a circuit diagram of a memory block shown in FIG. 1.

Referring to FIG. 1, the semiconductor memory device according to an example embodiment may include a memory array 110 including first through mth memory blocks MB1 to MBm, and a peripheral circuit PERI configured to perform a program operation on memory cells included in a selected page of the memory blocks MB1 to MBm.

Referring to FIG. 2, each of the memory blocks MB1 to MBm may include a plurality of strings ST1 to STk electrically coupled between bit lines BL1 to BLk and a common source line CSL. That is, the strings ST1 to STk may be respectively electrically coupled to the corresponding bit lines BL1 to BLk and electrically coupled in common to the common source line CSL. Each (e.g., ST1) of the strings may include source selection cells SSC1 to SSC3 electrically coupled to the common source line CSL, a plurality of memory cells C01 to Cn1, and drain selection cells DSC1 to DSC3 electrically coupled to the bit line BL1. The memory cells C01 to Cn1 may be electrically coupled in series between the selection cells SSC1 to SSC3 and DSC1 to DSC3. In the cell string ST1, the drain selection cells DSC1 to DSC3 may be interposed between the bit line BL1 and memory cells C01 to Cn1. Gates of the source selection cells SSC1 to SSC3 may be electrically coupled to a source selection line SSL. In the cell string ST1, the source selection cells SSC1 to SSC3 may be interposed between source selection line SSL and memory cells C01 to Cn1. Gates of the memory cells C01 to Cn1 may be respectively electrically coupled to word lines WL0 to WLn. Gates of the drain selection cells DSC1 to DSC3 may be electrically coupled to the drain selection line DSL. Although it is assumed for brevity that there are three source selection cells and the drain selection cells, the number of source selection cells and the drain selection cells is not limited thereto.

Each of the drain selection cells DSC1 to DSC3 and the source selection cells SSC1 to SSC3 may have a substantially similar structure as each of the memory cells C01 to Cn1. The drain selection cells DSC1 to DSC3 and the source selection cells SSC1 to SSC3 may be programmed by the peripheral circuit PERI, and have boosted threshold voltages. The drain selection cells DSC1 to DSC3 and the source selection cells SSC1 to SSC3 with boosted threshold voltages may operate as selection transistors. Because the gates of the drain selection cells DSC1 to DSC3 are electrically coupled to the drain selection line DSL and the gates of the source selection cells SSC1 to SSC3 are electrically coupled to the source selection line SSL, the drain selection cells DSC1 to DSC3 and the source selection cells SSC1 to SSC3 may be respectively programmed at the same time. Although FIG. 2 illustrates an example in which a drain selection transistor and a source selection transistor are respectively embodied by the drain selection cells DSC1 to DSC3 and the source selection cells SSC1 to SSC3, in some examples only the drain selection transistor is embodied by the drain selection cells DSC1 to DSC3 and the source selection transistor is embodied by a conventional transistor. In other examples, only the source selection transistor is embodied by the source selection cells SSC1 to SSC3 and the drain selection transistor is embodied by a conventional transistor.

The plurality of strings ST1 to STk may be disposed in a vertical direction to a substrate and 3-dimensionally embodied.

In an example embodiment, a distance between a first drain selection cell DSC1 and a second drain selection cell DSC2 may be greater than a distance between the second drain selection cell DSC2 and a third drain selection cell DSC3. Alternatively, the distance between the second drain selection cell DSC2 and the third drain selection cell DSC3 may be greater than the distance between the first drain selection cell DSC1 and the second drain selection cell DSC2.

In an example embodiment, the memory cells Cn1 to Cnk disposed adjacent to the drain selection cells DSC1 to DSC3 may be dummy memory cells. In one example, data is not stored in the dummy memory cells Cn1 to Cnk. Alternatively, dummy memory cells (not shown) may be further included between the memory cells Cn1 to Cnk and the drain selection cells DSC1 to DSC3. That is, in some embodiments, dummy memory cells (not shown) may be included in word lines further away from the drain selection cells DSC1 to DSC3 than the word line including the memory cells Cn1 to Cnk.

Memory cells included in the memory block may be divided in units of physical pages or logical pages. For example, memory cells C01 to C0k electrically coupled to one word line (e.g., WL0) may constitute one physical page PAGE0, which may become a basic unit of a program operation or read operation.

The peripheral circuit PERI may include a control circuit 120, a voltage supply circuit 130, a page buffer group 140, a column decoder 150, and an I/O circuit 160.

The control circuit 120 may output a voltage control signal VCON to the voltage supply circuit 130 for generating a required voltage to perform a program operation in response to a command signal CMD that is externally input through the I/O circuit 160. The control circuit 120 may also output a PB control signal PBCON to the page buffer group 140 for controlling page buffers PB1 to PBk included in the page buffer group 140. Also, the control circuit 120 may output a row address signal RADD to the voltage supply circuit 130 and a column address signal CADD to the column decoder 150 in response to an address signal ADD. The address signal ADD may be externally input through the I/O circuit 160. In particular, the control circuit 120 may output the voltage control signal VCON and the row address signal RADD such that the dummy memory cells Cn1 to Cnk are programmed before the drain selection cells DSC1 to DSC3 are programmed so that the drain selection cells DSC1 to DSC3 may function as the drain selection transistor. In other words, the peripheral circuit PERI may program the dummy memory cells before the drain selection cells DSC1 to DSC3 are programmed.

In response to the voltage control signal VCON of the control circuit 120, the voltage supply circuit 130 may supply operation voltages to local lines of a selected memory block required for programming memory cells, the local lines of the selected memory block may include the drain selection line DSL, the word lines WL0 to WLn, and the source selection line SSL. The voltage supply circuit 130 may include a voltage generating circuit and a row decoder.

The voltage generating circuit may output the operation voltages required for programming the memory cells to global lines in response to the voltage control signal VCON. For example, to enable a program operation, the voltage generating circuit may output a program voltage and a pass voltage to global lines. The program voltage may be applied to memory cells of a selected page and the pass voltage may be applied to unselected memory cells. In particular, when the drain selection cells DSC1 to DSC3 are programmed to use the drain selection cells DSC1 to DSC3 as the drain selection transistor, the voltage generating circuit may output the program voltage to the global lines such that the pass voltage is not applied to the memory cells of the selected page but the program voltage is directly applied to the memory cells of the selected page.

In response to row address signals RADDs sent from the control circuit 120, the row decoder may electrically couple the global lines with the local lines DSL, WL0 to WLn, and SSL so that operation voltages output by the voltage generating circuit to the global lines can be transmitted to the local lines DSL, WL0 to WLn, and SSL of a selected memory block of the memory array 110. Thus, a program voltage may be applied from the voltage generating circuit through a global word line to a local word line (e.g., WL0) electrically coupled to a selected cell (e.g., C01). Also, a pass voltage may be applied from the voltage generating circuit through global word lines to local word lines (e.g., WL1 to WLn) electrically coupled to unselected cells (C11 to CLn1). Thus, in one example, data may be stored in the selected cell C01 due to the program voltage.

The page buffer group 140 may include each of a plurality of page buffers PB1 to PBk electrically coupled to the memory array 110 through the bit lines BL1 to BLk. In response to the PB control signal PBCON, the page buffers PB1 to PBk of the page buffer group 140 may selectively precharge the bit lines BL1 to BLk according to data to be stored in the memory cells C01 to C0k.

The column decoder 150 may select the page buffers PB1 to PBk in response to the column address signal CADD output. That is, the column decoder 150 may sequentially transmit data to be stored in memory cells to the page buffers PB1 to PBk in response to the column address signal CADD.

To transmit externally input data to the page buffer group 140 and store the data in the memory cells during the program operation, the I/O circuit 160 may transmit the data to the column decoder 150 under control of the control circuit 120. The column decoder 150 may transmit the data from the I/O circuit 160 to the page buffers PB1 to PBk of the page buffer group 140 in the above-described manner. Thereafter, the page buffers PB1 to PBk may store the received data in latch circuits disposed therein.

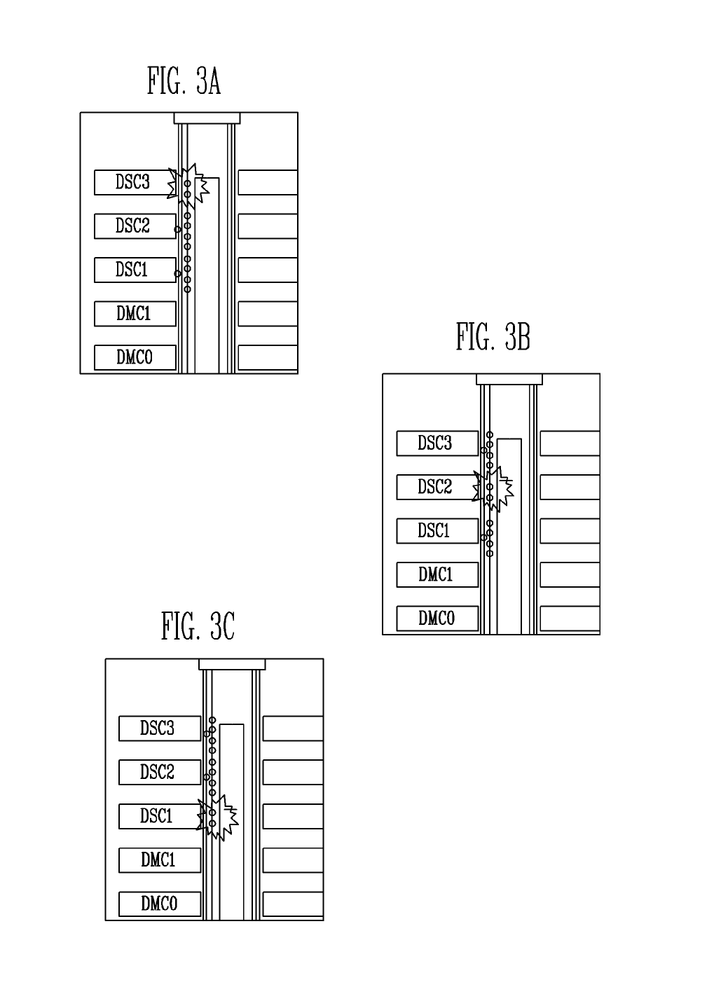

FIGS. 3A through 3C are diagrams for describing a relationship between threshold voltages of drain selection cells shown in FIG. 2 and channel boosting.

The gates of the drain selection cells DSC1 to DSC3 may be electrically coupled to the drain selection line. The drain selection cells DSC1 to DSC3 may be programmed simultaneously and have boosted threshold voltages. Accordingly, although the average threshold voltage of the drain selection cells DSC1 to DSC3 may be controlled using a typical method, it is difficult to accurately control a threshold voltage of each of the drain selection cells DSC1 to DSC3.

Referring to FIG. 3A, in one example case, five electrons may be trapped in the first and second drain selection cells DSC1 and DSC2, and two electrons may be trapped in the third drain selection cell DSC3. Because five electrons are trapped in drain selection cells DSC1 and DSC2 and only two electrons are trapped drain selection cell DSC3, a threshold voltage of each of the first and second drain selection cells DSC1 and DSC2 may be higher than a threshold voltage of the third drain selection cell DSC3.

Referring to FIG. 3B, in another example case, five electrons may be trapped in the first and third drain selection cells DSC1 and DSC3, and two electrons may be trapped in the second drain selection cell DSC2. Because five electrons are trapped in drain selection cells DSC1 and DSC3 and only two electrons are trapped drain selection cell DSC2, a threshold voltages of each of the first and third drain selection cells DSC1 and DSC3 may be higher than a threshold voltage of the second drain selection cell DSC2.

Referring to FIG. 3C, in still another example case, five electrons may be trapped in the second and third drain selection cells DSC2 and DSC3, and two electrons may be trapped in the first drain selection cell DSC1. Because five electrons are trapped in drain selection cells DSC2 and DSC3 and only two electrons are trapped drain selection cell DSC1, a threshold voltage of each of the second and third drain selection cells DSC2 and DSC3 may be higher than a threshold voltage of the first drain selection cell DSC1.

In the above-described three cases, although the drain selection cells DSC1 to DSC3 have the same average threshold voltage, the respective drain selection cells DSC1 to DSC3 may have different threshold voltages.

When the third drain selection cell DSC3 has a low threshold voltage, a leakage current of drain selection cell DSC3 may be higher. As the leakage current becomes higher, a channel boosting level may become lower. The third drain selection cell DSC3 may be the outermost drain selection cell relative the memory cells C01 to Cn1 coupled with the world lines WL0 to WLn of the memory block show in FIG. 2. When the third drain selection cell DSC3, which is an outermost drain selection cell, has a low threshold voltage, the channel boosting level may be lower. When the channel boosting level is low during a program operation, the semiconductor memory device may be vulnerable to a program disturbance. Accordingly, it is necessary to increase the threshold voltage of the outermost drain selection cell to prevent a program disturbance that may occur during a program operation.

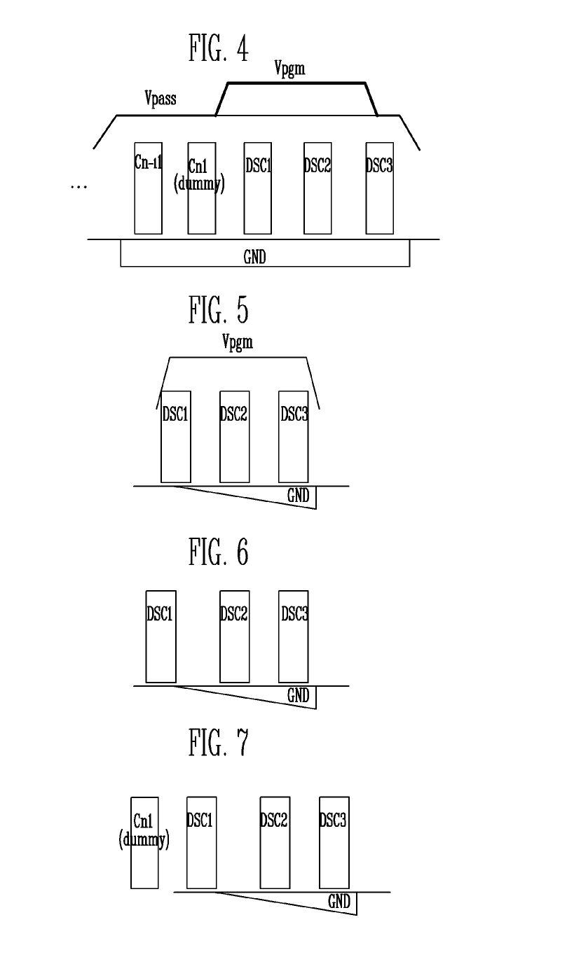

FIG. 4 is a conceptual diagram illustrating a method of operating a semiconductor memory device according to an example embodiment of the present disclosure.

Referring to FIG. 4, in the method of operating the semiconductor memory device according to an example embodiment of the present disclosure, to use drain selection cells DSC1 to DSC3 as a drain selection transistor, threshold voltages of the drain selection cells DSC1 to DSC3 may be raised before selected memory cells are programmed. To this end, a pass voltage Vpass may be initially applied to all memory cells of a cell string including the drain selection cells DSC1 to DSC3. Next, a program voltage Vpgm may be applied to gates of the drain selection cells DSC1 to DSC3. Since the drain selection cells DSC1 to DSC3 are grounded to the same degree, the third drain selection cell DSC3 may be likely to have a particularly low threshold voltage.

FIG. 5 is a conceptual diagram illustrating a method of operating a semiconductor memory device according to another example embodiment of the present disclosure.

Referring to FIG. 5, to increase a threshold voltage of a third drain selection cell DSC3, which is an outermost drain selection cell, a peripheral circuit may directly apply a program voltage Vpgm to gates of drain selection cells DSC1 to DSC3 without applying a pass voltage when the drain selection cells DSC1 to DSC3 are programmed.

When the program voltage Vpgm is a applied to the gates to DSC1 to DSC3 without applying a pass voltage, the third drain selection cell DSC3, the second drain selection cell DSC2, and the first drain selection cell DSC1 may be grounded such that the degree of grounding increases sequentially from DSC3 to DSC1. Accordingly, since the third drain selection cell DSC3 is programmed most effectively, the third drain selection cell DSC3 may have a threshold voltage greater than either the first or second drain selection cells DSC1 and DSC2.

FIG. 6 is a conceptual diagram illustrating a method of operating a semiconductor memory device according to another example embodiment of the present invention.

Referring to FIG. 6, to increase a threshold voltage of a third drain selection cell DSC3, which is an outermost drain selection cell, a program operation may be performed on a cell string in which a distance between a first drain selection cell DSC1 and a second drain selection cell DSC2 is greater than a distance between the second drain selection cell DSC2 and the third drain selection cell DSC3. Alternatively, a program operation may be performed on a cell string in which a distance between the second and third drain selection cells DSC2 and DSC3 is greater than a distance between the first and second drain selection cells DSC1 and DSC2.

When the distance between the three drain selection cells DSC1 to DSC3 varies as described above, the third drain selection cell DSC3, the second drain selection cell DSC2, and the first drain selection cell DSC1 may be grounded such that the degree of grounding of the drain selection cells DSC3 to DSC1 increases sequentially. Accordingly, since the third drain selection cell DSC3 is programmed most effectively, the third drain selection cell DSC3 may have a highest threshold voltage of the three drain selection cells DSC1 to DSC3.

FIG. 7 is a conceptual diagram illustrating a method of operating a semiconductor memory device according to another example embodiment of the present disclosure.

Referring to FIG. 7, to increase a threshold voltage of the third drain selection cell DSC3, which is an outermost drain selection cell, a dummy memory cell Cn1 disposed adjacent to a first drain selection cell DSC1 may be programmed before drain selection cells DSC1 to DSC3 are programmed.

When the dummy memory cell Cn1 is programmed before drain selection cells DSC1 to DSC3, the programming of the first drain selection cell DSC1 may be inhibited and the programming of the third drain selection cell DSC3 may be further activated. Thus, the third drain selection cell DSC3 may have a threshold voltage greater than the first and second drain selection cells DSC1 and DSC2.

As described above, in the method of operating the semiconductor memory device according to the example embodiment of the present disclosure, the threshold voltage of the third drain selection cell DSC3 may be greater relative to the second and third DSC2 and DSC3, when the threshold voltages of the drain selection cells DSC1 to DSC3 are boosted to use the drain selection cells DSC1 to DSC3 as a drain selection transistor. Thus, a leakage current may be reduced, and a channel boosting level may be increased to reduce the influence of a program disturbance.

In an example embodiment, the threshold voltage of the third drain selection cell DSC3, which is the outermost drain selection cell, may be further boosted using all of the methods described with reference to FIGS. 5, 6, and 7. That is, a program operation may be performed on a cell string in which a distance between the first and second drain selection cells DSC1 and DSC2, out of the drain selection cells DSC1 to DSC3, is greater than a distance between the second and third drain selection cells DSC2 and DSC3. However, the dummy memory cell Cn1 disposed adjacent to the first drain selection cell DSC1 may be programmed before the drain selection cells DSC1 to DSC3 are programmed, and a program voltage Vpgm may be directly applied to the gates of the drain selection cells DSC1 to DSC3 without applying a pass voltage during the programming of the drain selection cells DSC1 to DSC3. As a result, the threshold voltage of the third drain selection cell DSC3, which is the outermost drain selection cell, may be boosted to a higher level than the threshold voltages of each of the second and third DSC2 and DSC3 drain selection cells when one of the methods described with reference to FIGS. 5, 6, and 7 is used.

FIG. 8 is a flowchart illustrating a method of operating a semiconductor memory device according to another example embodiment of the present disclosure.

Referring to FIG. 8, a cell string including first memory cells configured to store data and second memory cells configured to be programmed and operate as a connection circuit between the first memory cells and an internal line may be provided (step S210). In the cell string, control gates of the second memory cells may be integrally connected, where integrally connected second memory cells may be memory cells that are connected within a same cell string. The internal line may comprise a bit line or a source line. The second memory cells may include drain selection cells configured to connect the bit line with the first memory cells, and the second memory cells may include source selection cells configured to connect the source line with the first memory cells. The first memory cells may comprise the memory cells C01 to Cn1 electrically coupled with the world lines WL0 to WLn of the memory block show in FIG. 2. Further, in one embodiment the second memory cells may interposed between a bit line and the first memory cells, and the second memory cells may be interposed between a source line and the first memory cells.

The second memory cells may be programmed such that an outermost of one of the second memory cells has the highest threshold voltage as compared to other second memory cells electrically coupled with a same cell string as the outermost one of the second memory cells (step S220). The outermost of one of the second memory cells may be disposed at a farthest distance from the first memory cells as compared to other second memory cells electrically coupled with a same cell string.

A selected memory cell from among the first memory cells may be programmed (step S230)

Accordingly, by boosting the threshold voltage of the outermost second memory cell to a level that is higher compared to other second memory cells, a leakage current may be reduced, and a channel boosting level may be increased to reduce the influence of a program disturbance.

FIG. 9 is a detailed flowchart of step S210 shown in FIG. 8.

Referring to FIG. 9, in step S210, a cell string in which a distance between any two of the second memory cells is greater than a distance between other memory cells may be provided (step S212).

In this case, a channel of the outermost drain selection cell is grounded to a greater degree such that there is an increase in a boosting of a threshold voltage of the outermost drain selection cell.

FIG. 10 is a detailed flowchart of step S220 shown in FIG. 8.

Referring to FIG. 10, when the second memory cells are programmed, a program voltage may be directly applied to the gates of the second memory cells without applying a pass voltage (step S222).

In this case, a degree to which a channel of the outermost drain selection cell is grounded may be increased to boost a threshold voltage of the outermost drain selection cell, such that the outermost drain selection cell may have a higher threshold voltage than other drain selection cells coupled to a same cell string.

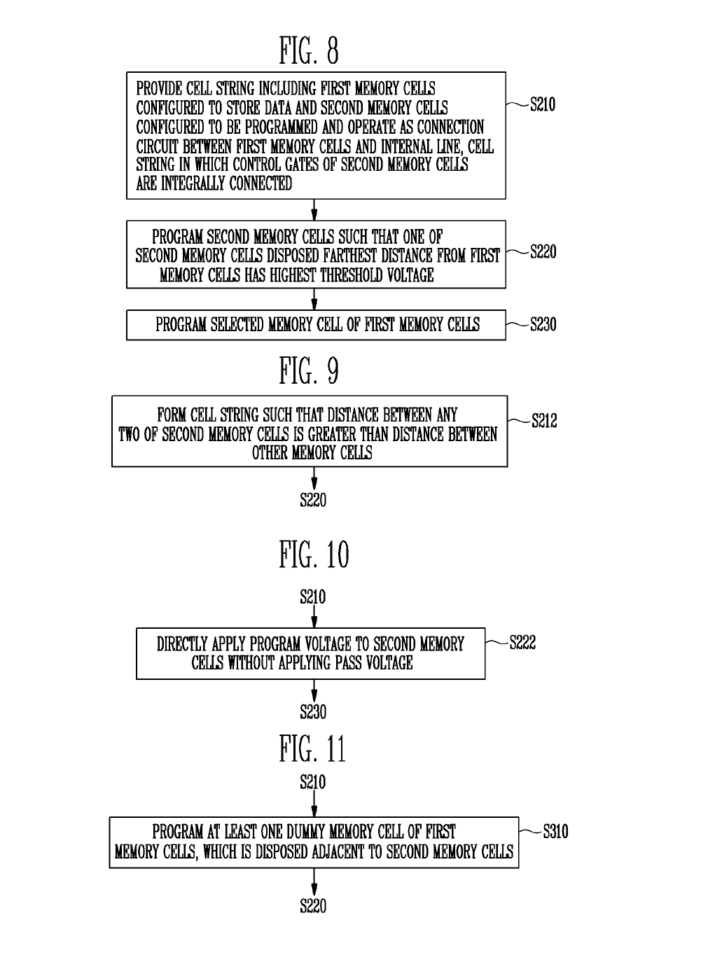

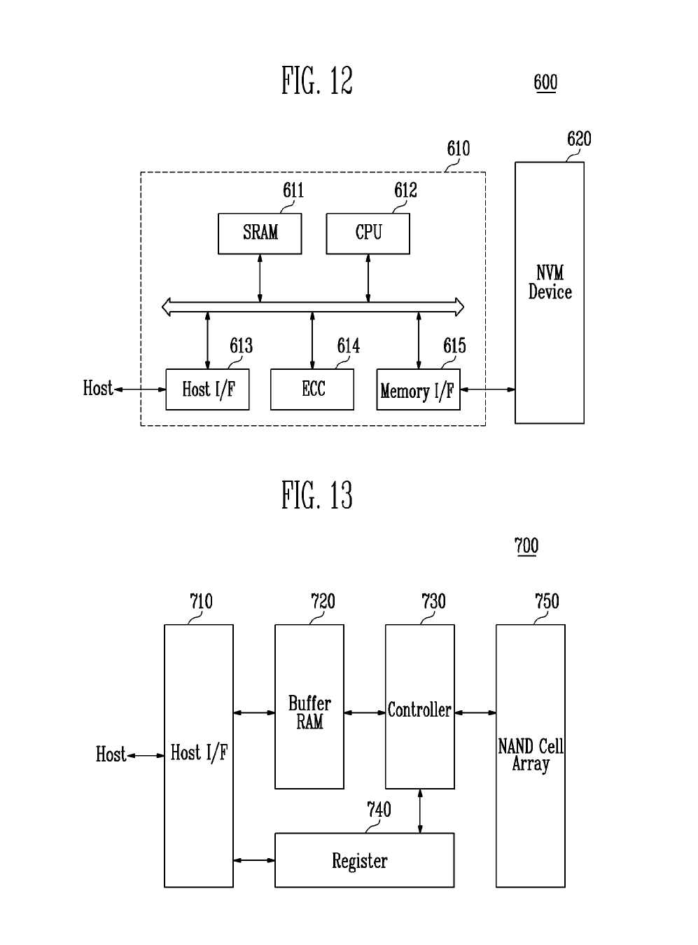

FIG. 11 is a detailed flowchart illustrating a method of operating the semiconductor memory device shown in FIG. 8.

Referring to FIG. 11, after step S210 and before step S220, that is, before the second memory cells are programmed, at least one dummy memory cell of the first memory cells, which is disposed adjacent to the second memory cells, may be programmed (step S310).

When the dummy memory cell is programmed before the second memory cells are programmed, the programming of the second memory cell disposed adjacent to the dummy memory cell may be inhibited, and the programming of the outermost second memory cell may be further activated. In one embodiment, the dummy memory cell may be included in a same cell string as the second memory cell. Thus, the threshold voltage of the outermost drain selection cell may be greatly boosted in comparison to the other drain selection cells comprising a same cell string.

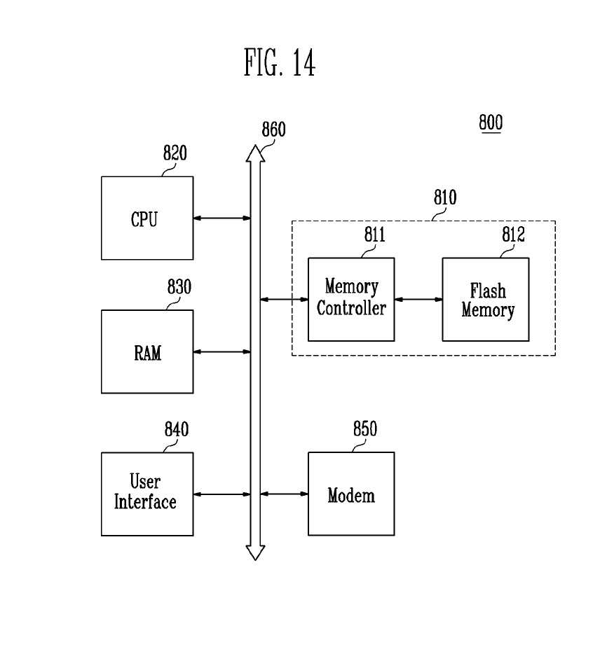

FIG. 12 is a simplified block diagram of a memory system 600 according to an example embodiment of the present disclosure.

Referring to FIG. 12, the memory system 600 according to the example embodiment of the present invention may include a nonvolatile memory device 620 and a memory controller 610.

The nonvolatile memory device 620 may include the above-described semiconductor memory device to be compatible with the memory controller 610, and operate using the above-described method. The memory controller 610 may be configured to control the nonvolatile memory device 620. The nonvolatile memory device 620 and the memory controller 610 may be combined and provided as a memory card or a solid-state disk (SSD). A static random access memory (SRAM) 611 may function as an operation memory of a processing unit 612. A host interface 613 may include a data exchange protocol of a host connected to the memory system 600. An error check and correct (ECC) block 614 may detect and correct errors in data read from a cell region of the nonvolatile memory device 620. A memory interface 615 may interface with the nonvolatile memory device 620 according to the present invention. The processing unit 612 may perform general control operations for exchanging data of the memory controller 610.

Although not shown in the drawings, it would be apparent to those of ordinary skill in the art that the memory system 600 according to the present invention may further include a read-only memory (ROM) (not shown) configured to store code data for interfacing with the host. The nonvolatile memory device 620 may be provided as a multi-chip package including a plurality of flash memory chips. The above-described memory system 600 according to the present invention may be provided as a highly reliably storage medium having improved operating characteristics. In particular, a memory system (e.g., an SSD) into which research has lately been conducted actively may include a flash memory device according to the present invention. In this case, the memory controller 610 may be configured to communicate with the outside (e.g., a host) through one of various interface protocols, such as a universal serial bus (USB), a multimedia card (MMC), peripheral component interface-express (PCI-E), serial advanced technology attachment (SATA), parallel-ATA (PATA), a small computer system interface (SCSI), an enhanced small device interface (ESDI), and an integrated drive electronics (IDE).

FIG. 13 is a simplified block diagram of a fusion memory device or a fusion memory system configured to perform a program operation, according to the above-described example embodiments of the present disclosure. For example, technical features according to the present disclosure may be applied to a OneNAND flash memory device 700, which is a fusion memory device.

The OneNAND flash memory device 700 may include a host interface 710 configured to exchange various pieces of information with devices using different protocols, a buffer RAM 720 configured to embed codes for driving the memory device 700 or temporarily store data, a controller 730 configured to control read and program operations and all states in response to external control signals and commands, a register 740 configured to store commands, addresses, and data (e.g., configuration data) configured to define system operating environments of the memory device 700, and a NAND flash cell array 750 including nonvolatile memory cells and an operating circuit including a page buffer. The OneNAND flash memory device 700 may program data using the above-described method in response to a write request from the host.

FIG. 14 illustrates a schematic computing system 800 including a flash memory device 812 according to an example embodiment of the present invention.

The computing system 800 according to the present disclosure may include a microprocessor (MP) 820, a RAM 830, a user interface 840, a modem 850 (e.g., a baseband chipset), and a memory system 810, all of which may be electrically coupled to a system bus 860. When the computing system 800 according to the present disclosure is a mobile device, the computing system 800 may further include a battery (not shown) configured to supply an operating voltage to the computing system 800. Although not shown in the drawings, it would be apparent to those of ordinary skill in the art that the computing system 800 according to the present invention may further include an application chipset, a camera image processor (CIS), or a mobile dynamic RAM (mobile DRAM). The memory system 810, for example, may constitute an SSD using a nonvolatile memory configured to store data. Alternatively, the memory system 810 may be provided as a fusion flash memory (e.g., OneNAND flash memory).

In a method of operating a semiconductor memory device according to example embodiments of the present disclosure, a threshold voltage of an outermost memory cell can be raised to the highest degree when threshold voltages of memory cells are boosted to use the memory cells as a selection transistor. Thus, a leakage current can be reduced, and a channel boosting level can be increased to reduce the influence of program disturbance.

Accordingly, data reliability can be improved, and the yield and performance of semiconductor memory devices can be increased.

The above-described example embodiments of the present disclosure may be embodied not only using devices and methods but also using a program capable of implementing functions corresponding to a construction according to an example embodiment of the present disclosure or a recording medium on which the program is recorded. Also, the program or recording medium may be easily construed by programmers skilled in the art.

Typical example embodiments are disclosed in the above description and the drawings. Although specific terms are employed, they are used in a generic and descriptive sense only and not for purposes of limitation. It will be understood by those of ordinary skill in the art that various changes in form and details may be made to the disclosed embodiments without departing from the spirit and scope of the present disclosure as defined by the following claims.

What is claimed is:

1. A cell string comprising:
first memory cells configured to store data; and
second memory cells configured to be programmed and operate as a connection circuit between the first memory cells and an internal line,
wherein control gates of the second memory cells are integrally connected.

2. The cell string of claim 1, wherein the second memory cells are programmed such that one of the second memory cells, which is disposed at a farthest distance from the first memory cells, has a highest threshold voltage as compared to other second memory cells included in a same cell string as the one of the second memory cells.

3. The cell string of claim 1, wherein the second memory cells are interposed between a bit line and the first memory cells.

4. The cell string of claim 1, wherein the second memory cells are interposed between a source line and the first memory cells.

5. The cell string of claim 1, wherein the second memory cells are interposed between a bit line and the first memory cells and between a source line and the first memory cells.

6. The cell string of claim 1, wherein a program voltage is applied to the second memory cells without applying a pass voltage during a program operation.

7. The cell string of claim 1, wherein a distance between any two of the second memory cells is greater than a distance between other memory cells.

8. The cell string of claim 1, wherein at least one of the first memory cells, which is adjacent to the second memory cells, is a dummy memory cell.

9. The cell string of claim 8, wherein the dummy memory cell is programmed before the second memory cells.

10. A semiconductor memory device comprising:
a cell string including first memory cells configured to store data and second memory cells configured to be programmed and operate as a connection circuit between the first memory cells and an internal line, control gates of the second memory cells being integrally connected; and
a peripheral circuit configured to program the second memory cells such that one of the second memory cells, which is disposed at a farthest distance from the first memory cells, has a highest threshold voltage.

11. The device of claim 10, wherein in the cell string, the second memory cells are interposed between a bit line and the first memory cells.

12. The device of claim 10, wherein in the cell string, the second memory cells are interposed between a source line and the first memory cells.

13. The device of claim 10, wherein in the cell string, the second memory cells are interposed between a bit line and the first memory cells and between a source line and the first memory cells.

14. The device of claim 10, wherein the peripheral circuit directly applies a program voltage to the second memory cells without applying a pass voltage during a program operation.

15. The device of claim 10, wherein in the cell string, a distance between any two of the second memory cells is greater than a distance between other memory cells.

16. The device of claim 10, wherein in the cell string, at least one of the first memory cells, which is adjacent to the second memory cells, is a dummy memory cell.

17. The device of claim 16, wherein the peripheral circuit programs the dummy memory cell before the peripheral circuit programs the second memory cells.

18. A method of operating a semiconductor memory device, the method comprising:
providing a cell string including first memory cells configured to store data and second memory cells configured to be programmed and operate as a connection circuit between the first memory cells and an internal line, control gates of the second memory cells being integrally connected;
programming the second memory cells such that one of the second memory cells, which is disposed at a farthest distance from the first memory cells, has a highest threshold voltage; and
programming a selected memory cell of the first memory cells.

19. The method of claim 18, wherein the programming of the second memory cells comprises directly applying a program voltage to the second memory cells without applying a pass voltage.

20. The method of claim 18, before programming the second memory cells, further comprising programming at least one dummy memory cell of the first memory cells, which is adjacent to the second memory cells.
